(19) United States
(12) Patent Application Publication
(10) Pub. No.: US 2026/0047066 A1
(43) Pub. Date: Feb. 12, 2026

(54) SEMICONDUCTOR DEVICE AND METHOD OF MANUFACTURING THE SAME

(71) Applicant: Winbond Electronics Corp., Taichung City (TW)

(72) Inventor: Hao-Chuan CHANG, Taichung City (TW)

(73) Assignee: Winbond Electronics Corp., Taichung City (TW)

(21) Appl. No.: 19/292,429

(22) Filed: Aug. 6, 2025

(30) Foreign Application Priority Data
Aug. 9, 2024 (TW) 113129988

(51) Int. Cl. H10B 12/00

(52) U.S. Cl. CPC H10B 12/09; H10B 12/315; H10B 12/50

(57) ABSTRACT

A method of manufacturing a semiconductor device includes providing a stack of dielectric material layers over a substrate, wherein the substrate has an array region and a periphery region. The method also includes forming several placement holes of capacitor structures in the stack of dielectric material layers, and forming the capacitor structures in the placement holes. The capacitor structures include several storage capacitors in the array region and several dummy capacitors surrounding the storage capacitors. Each storage capacitor has a first critical dimension at the top surface of the stack of dielectric material layers. Each dummy capacitor has a second critical dimension at the top surface of the stack of dielectric material layers. The second critical dimension is smaller than the first critical dimension and larger than one-third of the first critical dimension.

### CROSS REFERENCE TO RELATED APPLICATIONS

This Application claims priority of Taiwan Patent Application No. 113129988, filed on Aug. 9, 2024, the entirety of which is incorporated by reference herein.

### BACKGROUND OF THE INVENTION

### Field of the Invention

The present invention relates to semiconductor devices including capacitor structures with high aspect ratios and methods of manufacturing the same.

### Description of the Related Art

Many challenges arise as device manufacturing technology trends toward device sizes being scaled down. For example, during the process of fabricating a capacitor structure with a high aspect ratio, variations in the dimensions of the openings on the patterned layer at the array edge can be significant. These variations are caused by several factors, such as the presence of multiple layers between the patterned layer, which defines the position of the capacitor structure's placement hole, and the patterned photoresist used to mask the peripheral area. The sidewalls of the patterned photoresist may be sloped or displaced from their intended position, which can result in variations in the dimensions of the exposed openings in the patterned layer. As a result, due to the etching load effect, the large-sized placement holes of the dummy capacitors are prone to extending obliquely at the bottom, thereby coming into contact with the placement holes of adjacent storage capacitors. This can lead to short-circuits between the dummy capacitor and the storage capacitor formed in these holes, thereby reducing the yield of the semiconductor device. If the issue of significant size variation in the placement holes of the dummy capacitors is not addressed, it will be necessary to include more dummy capacitors to prevent contact between the defective dummy capacitors and the storage capacitors. This approach, however, will hinder the miniaturization of semiconductor devices.

### BRIEF SUMMARY OF THE INVENTION

According to the semiconductor device and its manufacturing method proposed in the present disclosure, the issue of large variations in the size of the placement hole of the dummy capacitor can be addressed, thereby alleviating the problem of short circuits between the dummy capacitor and the storage capacitor.

Some embodiments of the present disclosure provide a method of manufacturing a semiconductor device, including forming a dielectric material stack over a substrate having an array region and a periphery region; forming placement holes of multiple capacitor structures in a dielectric material stack; and forming capacitor structures in these placement holes, and the capacitor structures includes a plurality of storage capacitors in the array region, wherein each of the storage capacitors has a first critical dimension at the top surface of the dielectric material stack; and a plurality of dummy capacitors surrounding the storage capacitors, wherein each of the dummy capacitors has a second critical dimension at the top surface of the dielectric material stack, wherein the second critical dimension is smaller than the first critical dimension and larger than one-third of the first critical dimension.

Some embodiments of the present disclosure provide a semiconductor device including a substrate, a dielectric material stack, and a plurality of capacitor structures in the dielectric material stack. The substrate has an array region and a periphery region; the dielectric material stack over the substrate; and a plurality of capacitor structures in a dielectric material stack. The capacitor structures includes a plurality of storage capacitors in the array region, wherein each of the storage capacitors has a first critical dimension at the top surface of the dielectric material stack; a plurality of dummy capacitors surrounding these storage capacitors, where each of the dummy capacitors has a second critical dimension at the top surface of the dielectric material stack, where the second critical dimension is smaller than the first critical dimension and larger than one-third of the first critical dimension.

According to the semiconductor device and its manufacturing method provided by the present disclosure, the depth and pattern uniformity of the dummy capacitor are improved, and the depth of the placement hole of the dummy capacitor is controlled to be smaller than the depth of the placement hole of the storage capacitor, which avoids short circuits between adjacent capacitor structures, thereby improving the yield of semiconductor devices.

### BRIEF DESCRIPTION OF THE DRAWINGS

FIGS. 1 and 2A-2D are schematic diagrams of semiconductor devices in some intermediate manufacturing stages according to some embodiments of the present disclosure.

FIGS. 3A, 4A, 5A, 6A, and 7A are schematic three-dimensional views of a semiconductor device in some intermediate manufacturing stages to form a patterned sacrificial target layer according to some embodiments of the present disclosure. FIGS. 3B, 4B, 5B, 6B, and 7B are the top views of FIGS. 3A, 4A, 5A, 6A, and 7A respectively.

FIGS. 8 and 9 are respectively a partial top view and a schematic cross-sectional view of the placement hole of the capacitor structure in the semiconductor device according to some embodiments of the present disclosure.

FIG. 10 is a schematic cross-sectional view of a capacitor structure in a semiconductor device according to some embodiments of the present disclosure.

### DETAILED DESCRIPTION OF THE INVENTION

The following content provides different examples for implementing different components of embodiments of the invention. Of course, these are only examples and are not intended to limit the present invention. For example, if the description refers to a first component being formed on a second component, unless otherwise specifically excluded, the first component and the second component may be in direct contact or may not be in direct contact. In addition, for the purpose of simplicity and clarity, embodiments of the present invention may use the same or similar numeral references for the same or similar elements in many examples. Furthermore, the manufacturing method of the semiconductor device of the present invention may be applied to, for example, DRAM, or any semiconductor device with a columnar capacitor structure. Furthermore, although the cross-sectional views of the embodiments only illustrate a portion of the array region and an adjacent portion of the periphery region for illustration purposes, the present disclosure is not limited to the illustrated features.

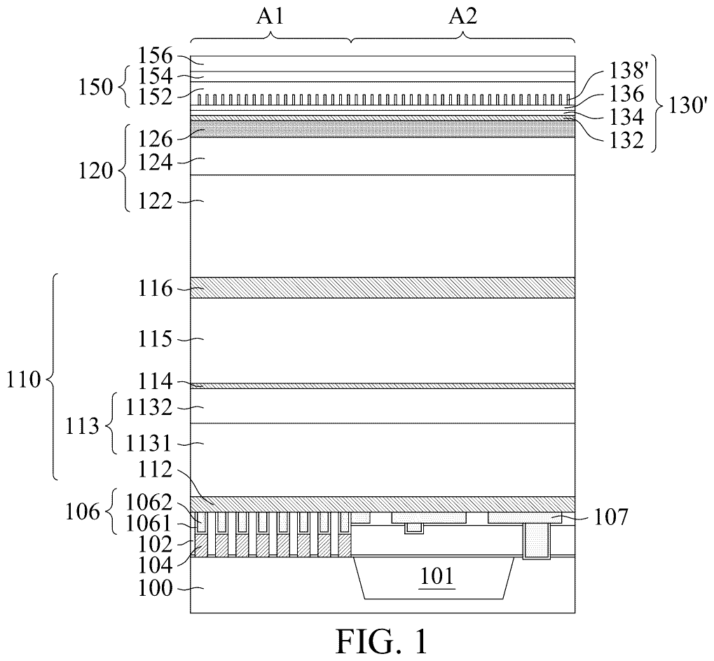

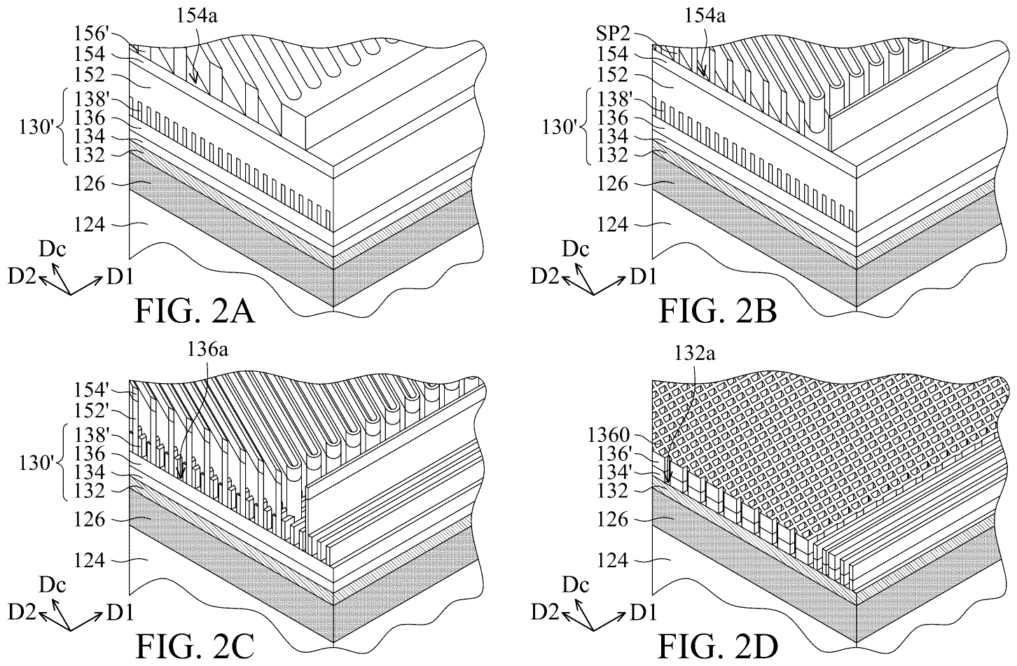

Refer to FIGS. 1 and 2A-2D, a method of manufacturing the dielectric material stack 110 and the patterned sacrificial layer 136′ of the semiconductor device is described. As shown in FIG. 1, substrate 100 includes an array region A1 and a periphery region A2 adjacent to the array region A1. The substrate 100 may include semiconductor materials, such as silicon, gallium arsenide, gallium nitride, germanium silicide, or combinations thereof. In one embodiment, the substrate 100 is a silicon-on-insulator (SOI). The isolation structure 101 may be formed in substrate 100 to isolate multiple active regions in substrate 100. In some embodiments, an isolation structure 101 may also be formed between the array region A1 and the periphery region A2 in the substrate 100. When the semiconductor device is a DRAM, various components, such as word lines (not shown) and/or bit lines (not shown), may be formed in the substrate 100.

In this embodiment, the insulating layer 102 may be formed on the substrate 100, and the contact plug 104 in the array region A1 may be formed in the insulating layer 102. The contact plug 104 is used to electrically connect to the active area of substrate 100. The insulating layer 102 may be a single layer or a multi-layer structure, for example, including an oxide layer and a nitride layer disposed in sequence. In one embodiment, metal contact wires 107 in the periphery region A2 may be formed in the insulating layer 102.

In some embodiments, barrier structure 106 may be formed over contact plug 104. The bottom surface of barrier structure 106 may fully cover the top surface of the contact plug 104 to prevent etchant in subsequent processes from penetrating and damaging the contact plug 104 and components in the substrate 100. In this example, barrier structure 106 includes the first barrier layer 1061 and the second barrier layer 1062. The first barrier layer 1061 covers the sidewalls and bottom surface of the second barrier layer 1062. The first barrier layer 1061 includes, for example, titanium, titanium nitride, tungsten nitride, tantalum, tantalum nitride or a combination of the foregoing. The second barrier layer 1062 includes, for example, tungsten, copper, other metal materials with better conductivity, or a combination thereof to provide a lower resistance value.

Afterwards, a dielectric material stack 110 is formed over the substrate 100. The dielectric material stack 110 may include a first support layer 112, a first interlayer insulating layer 113, a second support layer 114, a second interlayer insulating layer 115, and a third support layer 116, which are formed in sequence to cover the insulating layer 102 and the barrier structure 106. By forming the first support layer 112, the second support layer 114 and the third support layer 116 that are separated from each other, the subsequently formed capacitor structure with a high aspect ratio is less likely to collapse. The first support layer 112, the second support layer 114 and the third support layer 116 may include, for example, silicon nitride. The first interlayer insulating layer 113 and the second interlayer insulating layer 115 may include, for example, an oxide material. The first interlayer insulating layer 113 may include a first insulating sub-layer 1131 and a second insulating sub-layer 1132. The second interlayer insulating layer 115 and the second insulating sub-layer 1132 may include the same material.

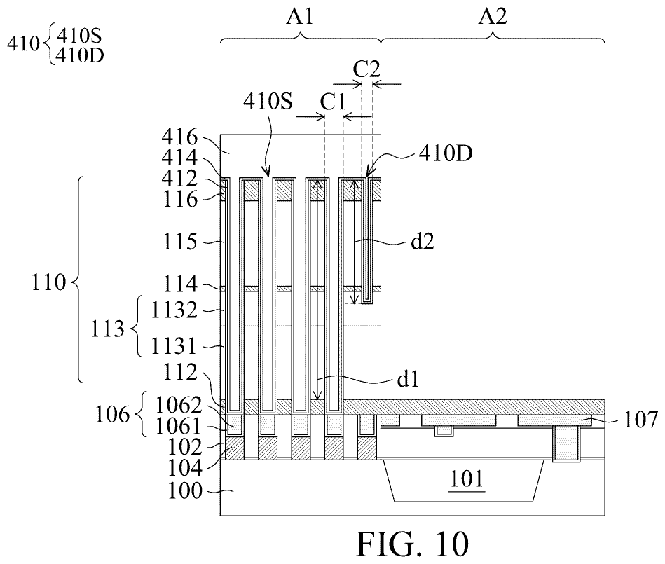

In subsequent processes, a capacitor structure is formed above the contact plug 104 in the array region A1. For example, a placement hole is formed in the dielectric material stack 110, and a capacitor structure (e.g., 410 in FIG. 10) is formed in the placement hole. The capacitor structure can be electrically connected to the contact plug 104 via the barrier structure 106. The capacitor structure includes a storage capacitor in the array region A1 and a dummy capacitor at the edge of the array region A1. The following describes the manufacturing method of the placement hole of the capacitor structure in some embodiments.

As shown in FIG. 1, a pattern transfer layer 120, a first material stack 130′, a second material stack 150 and a photoresist material layer 156 are sequentially formed over the dielectric material stack 110. The pattern transfer layer 120 may include a polysilicon layer 122, an oxide layer 124, and a sacrificial target layer 126 sequentially formed on the third support layer 116. The sacrificial target layer 126 may be, for example, diamond-like carbon, an amorphous carbon film, a high-selectivity transparent carbon-containing layer, or other suitable carbon-containing material. In this example, sacrificial target layer 126 is a spin-on-carbon (SOC) layer. The first material stack 130′ may include a nitride layer 132, an oxide layer 134, a sacrificial layer 136, and a plurality of oxide strips 138′ sequentially formed on the pattern transfer layer 120. The material of the sacrificial layer 136 may include, for example, polycrystalline silicon. The thickness of each material layer of the first material stack 130′ is, for example, but not limited to, smaller than the thickness of each material layer of the pattern transfer layer 120. The oxide strips 138′ extending along the first direction D1 may be formed by a self-aligned double patterning (SADP) process. The second material stack 150 includes, for example, a spin-on-glass (SOG) layer 152 and an oxide layer 154 formed in sequence.

Then, the SADP process as shown in FIGS. 2A-2D may be performed. As shown in FIG. 2A, a photolithographic patterning process is performed on the photoresist material layer 156 to form a patterned photoresist layer 156′ over the oxide layer 154. The patterned photoresist layer 156′ includes photoresist strips extending along the direction Dc and spaced apart, and the photoresist strips expose the top surface 154a of the oxide layer 154. Afterward, referring to FIG. 2B, spacers SP2 are formed on two opposite side walls of each photoresist strip (used as a mandrel) of the patterned photoresist layer 156′. Afterward, the patterned photoresist layer 156′ is removed. Next, referring to FIG. 2C, the spacer SP2 is used as an etching mask to sequentially transfer the mask pattern to the underlying oxide layer 154 and SOG layer 152 to form the oxide layer 154′ and the SOG strips 152′ on the oxide strips 138′ and expose the top surface 136a of the sacrificial layer 136.

Please refer to FIG. 2D. After that, the oxide layer 154′, the SOG strips 152′, and the oxide strips 138′ are used as etching masks to etch the underlying sacrificial layer 136 and the oxide layer 134, thereby forming the patterned sacrificial layer 136′ and the patterned oxide layer 134′, in which the nitride layer 132 serves as an etching stop layer. Therefore, the patterned sacrificial layer 136′ and the underlying patterned oxide layer 134′ expose the top surface 132a of the nitride layer 132.

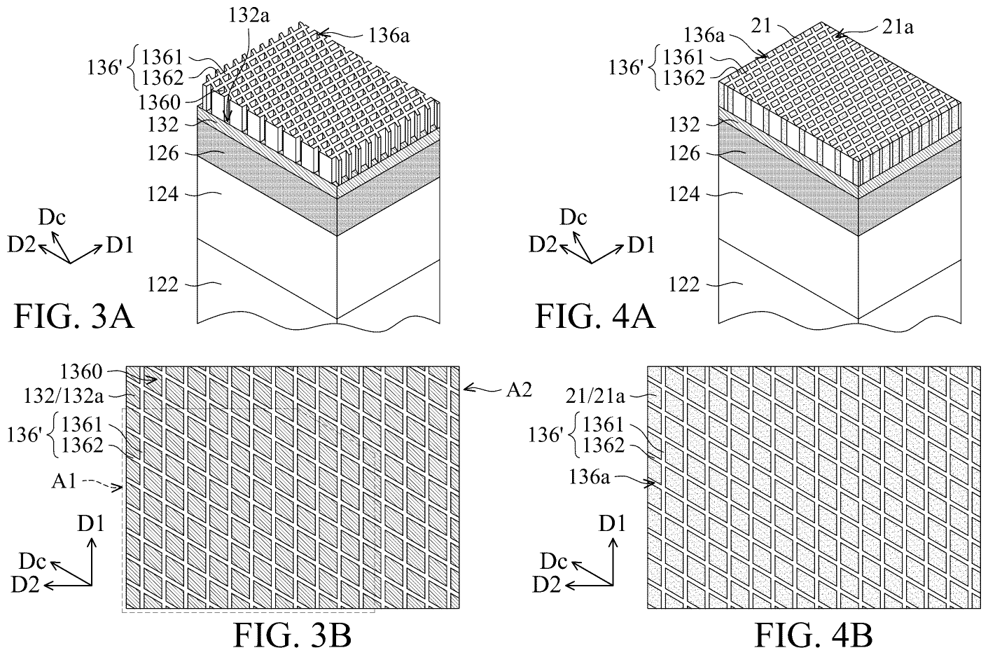

Since the patterned oxide layer 134′ and the patterned sacrificial layer 136′ have the same pattern, the patterned oxide layer 134′ may be omitted from the following descriptions and FIGS., where the patterned sacrificial layer 136′ represents itself, and potentially the patterned oxide layer 134′ beneath the patterned sacrificial layer 136′. In addition, only part of the semiconductor device is shown in FIGS. 2A-7A, the omitted layers and components may be referred to FIG. 1 and the above-related descriptions. FIGS. 3B-7B are the top views of FIGS. 3A-7A.

Please refer to FIGS. 3A and 3B. Only a part of the array region A1 (shown by a dotted line) and a part of the periphery region A2 are shown here. FIG. 3A is a partially enlarged schematic diagram of a semiconductor device manufactured according to the steps of FIG. 2D. In some embodiments, the patterned sacrificial layer 136′ includes polycrystalline silicon strips 1361 extending along the first direction D1 and polycrystalline silicon strips 1362 extending along the direction Dc. The staggered polycrystalline silicon strips 1361 and 1362 define a plurality of through holes 1360. Through holes 1360 expose the top surface 132a of nitride layer 132.

Refer to FIGS. 4A and 4B. Afterward, fillers 21 are formed in the through holes 1360. The filler 21 fills through hole 1360 and contacts the top surface 132a of the nitride layer 132. Furthermore, the material of the filler 21 is different from that of the patterned sacrificial layer 136′ and the nitride layer 132. The material of the filler 21 may include oxide, such as silicon oxide. The top surface 21a of the filler 21 may be substantially coplanar with the top surface 136a of the patterned sacrificial layer 136′.

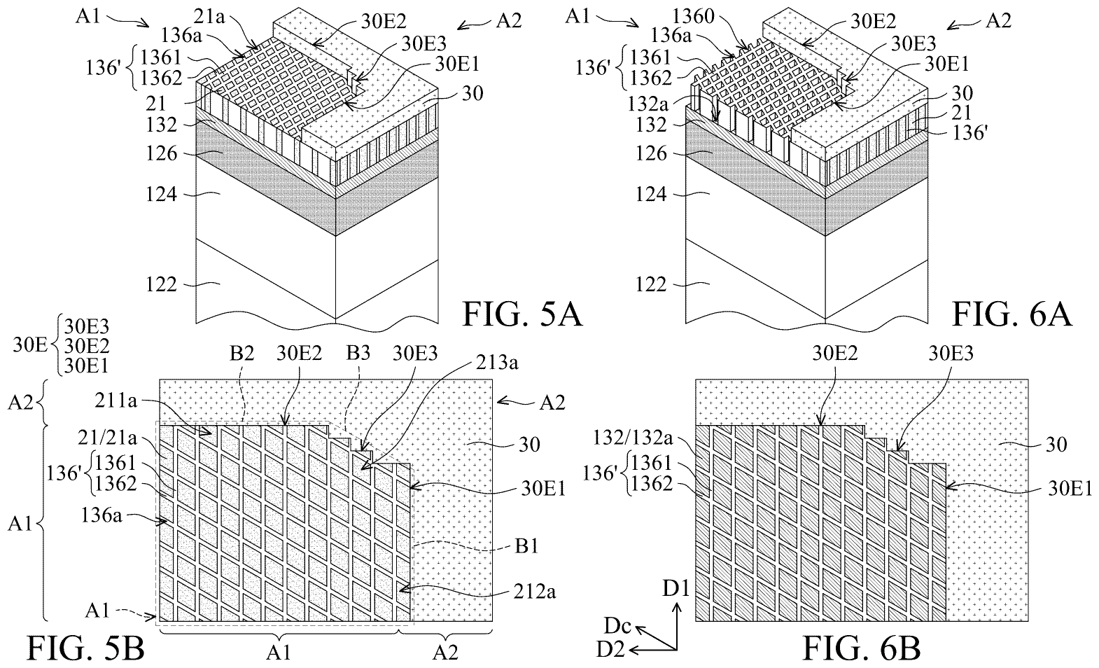

Refer to FIGS. 5A and 5B. Afterward, according to some embodiments of the present disclosure, a patterned mask layer 30 is formed on the patterned sacrificial layer 136′ and the fillers 21. Specifically, the patterned mask layer 30 covers the patterned sacrificial layer 136′ and the fillers 21 in the periphery region A2, and exposes the patterned sacrificial layer 136′ and the fillers 21 in the array region A1 (corresponding to the positions of the placement holes of the capacitor structures).

Specifically, the opening edge 30E of the patterned mask layer 30 as shown in FIGS. 5A and 5B includes a first edge 30E1, a second edge 30E2, and a third edge 30E3 connecting the first edge 30E1 and the second edge 30E2. The first edge 30E1 is adjacent to the first edge B1 of the array region A1 (e.g., positioned on the outside of the polysilicon strip 1361 that is closest to the first edge B1). The second edge 30E2 is adjacent to the second edge B2 of the array region A1 (e.g., located outside the polycrystalline silicon strip 1361 which is closest to the second edge B2). The third edge 30E3 is adjacent to the third edge B3 of the array region A1 (e.g., located outside the polycrystalline silicon strip 1361 which is closest to the third edge B3).

In accordance with the described embodiment, the formation of the patterned mask layer 30 enables precise adjustment of the opening edge position. This ensures that the top surfaces (such as 211a, 212a, and 213a) of the fillers 21 within array region A1, particularly those nearest to the periphery region A2, exhibit uniform or comparable exposed areas. As a result, the dimensional consistency (including hole size and shape) of the subsequently formed patterned sacrificial target layer 126′ is effectively controlled. Consequently, the second placement holes 42 for placing the dummy capacitors ( ), generated following pattern transfer to the dielectric material stack 110, achieve consistent or similar dimensions.

Please refer to FIGS. 6A and 6B. Afterward, the fillers 21 not covered by the patterned mask layer 30 are removed, for example, by a wet etching process without substantially affecting the patterned sacrificial layer 136′ and nitride layer 132, leaving the fillers 21 covered by the patterned mask layer 30.

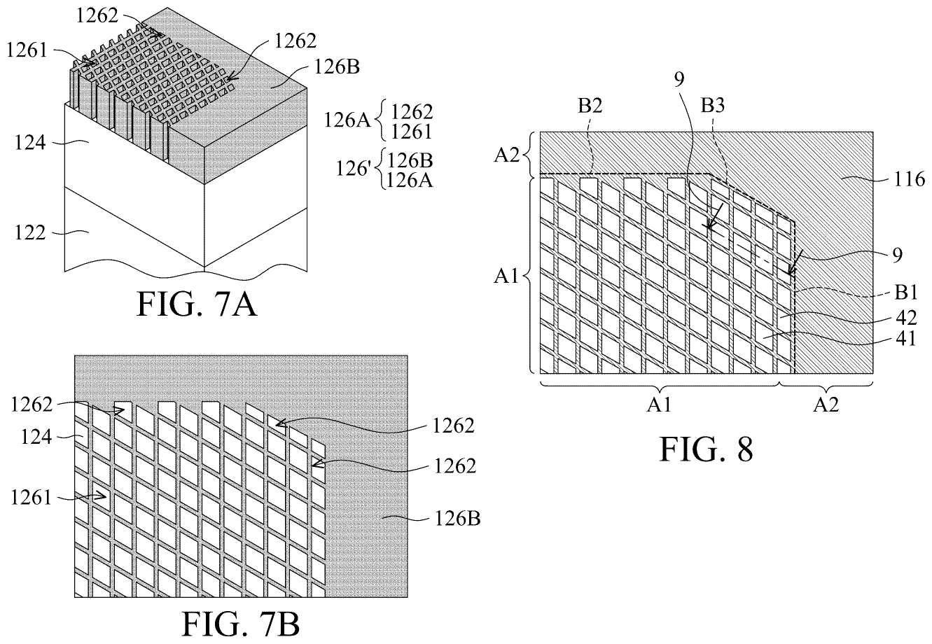

Please refer to FIGS. 7A and 7B. After that, the combination of the patterned mask layer 30 and the sacrificial layer 136′ is used as a mask to transfer the pattern to the sacrificial target layer 126 thereunder, thereby forming the patterned sacrificial target layer 126′. The patterned sacrificial target layer 126′ includes an array pattern 126A and a periphery pattern 126B corresponding to the array region A1 and the periphery region A2 respectively. Specifically, the array pattern 126A includes a plurality of first holes 1261 and a plurality of second holes 1262 around the first holes 1261. Furthermore, the first hole 1261 corresponds to the position of the placement hole 41 (labeled in FIG. 8) of the storage capacitor subsequently formed in the dielectric material stack 110. The second hole 1262 corresponds to the position of placement hole 42 of the dummy capacitor (labeled in FIG. 8) subsequently formed in the dielectric material stack 110. The second hole 1262 may be abutting or adjacent to the periphery pattern 126B. In this embodiment, the second holes 1262 have openings with the same or similar size, and the second hole 1262 is smaller than the first hole 1261. The described size may refer to shape and/or area and/or width.

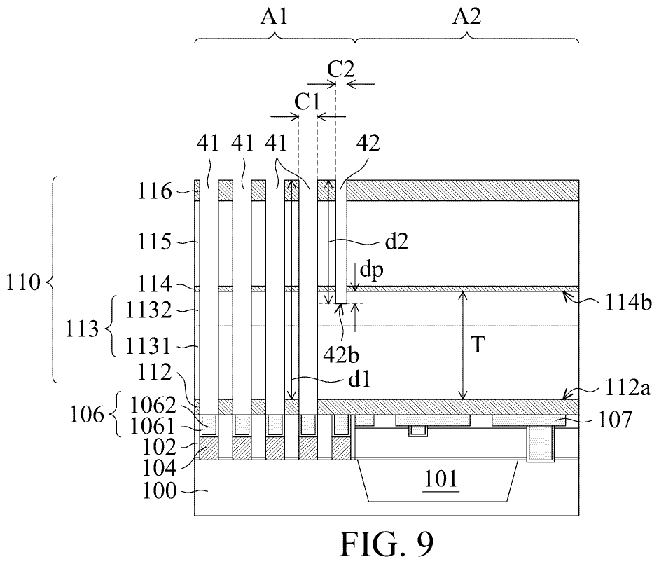

As shown in FIGS. 8 and 9, the array pattern 126A and the periphery pattern 126B of the patterned sacrificial target layer 126′ are then transferred to the underlying dielectric material stack 110, thereby forming placement holes for a capacitor structures (e.g., including a storage capacitor and a dummy capacitor). In this embodiment, the array pattern 126A and the periphery pattern 126B of the patterned sacrificial target layer 126′ are sequentially transferred to the oxide layer 124, the polysilicon layer 122, and the dielectric material stack 110. FIG. 9 is a schematic cross-sectional view of a semiconductor device taken along line 9-9 in FIG. 8 at an intermediate manufacturing stage. In this example, the placement holes of the capacitor structures formed in the dielectric material stack 110 include a plurality of first placement holes 41 in the array region A1, and a plurality of second placement holes 42 surrounding the first placement holes 41. The first placement hole 41 and the second placement hole 42 respectively correspond to the first hole 1261 and the second hole 1262 of the patterned sacrificial target layer 126′. The second placement hole 42 may be smaller than the first placement hole 41. The second placement holes 42 have openings with the same or similar size.

According to some examples, as shown in FIG. 9, the difference between the maximum value and the minimum value of the critical dimensions C2 among second placement holes 42 at the top surface of the dielectric material stack 110 is less than one-tenth of the average value. Alternatively, the difference between the maximum value and the minimum value of critical dimensions C2 is less than or equal to 10 nm. Alternatively, the uniformity of critical dimensions C2 (U %=(maximum value-minimum value)/2*average value) is ranged from 0.5˜1 nm.

Furthermore, the larger the holes in the patterned sacrificial target layer 126′, the larger and deeper the placement holes of the subsequently formed capacitor structures. According to the manufacturing method of the embodiment, the opening and depth of the second placement hole 42 may be controlled by adjusting the size of the second hole 1262 of the patterned sacrificial target layer 126′, so that the second placement hole 42 reaches a predetermined depth that may be well supported in the dielectric material stack 110.

Specifically, according to a preferred embodiments, the opening size of the second placement hole 42 (e.g., critical dimension C2) is smaller than the opening size of the first placement hole 41 (e.g., critical dimension C1), and the depth d2 of the second placement hole 42 is smaller than the depth d1 of the first placement hole 41, as shown in FIG. 9. For example, critical dimension C2 is larger than one-third of critical dimension C1 and smaller than critical dimension C1. The bottom of the second placement hole 42 may stop at a position that can be restricted by the upper support layer (e.g., the third support layer 116) and the middle support layer (e.g., the second support layer 114).

In another preferred embodiment, the second placement hole 42 may extend through the third supporting layer 116, the second interlayer insulating layer 115, and the second supporting layer 114, and stop in the first interlayer insulating layer 113. According to the manufacturing method described in this disclosure, adjusting the opening size of the second placement hole 42 enables precise control so that the bottom surface 42b of the second placement hole 42 remains within the first interlayer insulating layer 113 and does not extend significantly beyond the bottom surface 114b of the second support layer 114. Therefore, the distance between the bottom surface 42b of the second placement hole 42 and the bottom surface 114b of the second supporting layer 114 may be less than the distance between the bottom surface 42b of the second placement hole 42 and the top surface 112a of the first supporting layer 112.

In yet another preferred embodiment, the ratio of the vertical distance dp from the bottom surface 42b of each second placement hole 42 to the bottom surface 114b of the second support layer 114 and the thickness T of the first interlayer insulating layer 113 (i.e. the distance from the first support layer 112 to the second support layer 114) is ranged from about 0.01 to about 0.2. As a result, by the limiting and supporting effects of the second supporting layer 114 and the third supporting layer 116 on the second placement hole 42, the second placement hole 42 may be prevented from extending obliquely toward the adjacent first placement hole 41.

Furthermore, the second placement hole 42 produced according to some embodiments of the present disclosure may have substantially the same or similar depth d2. For example, the difference in the vertical distance dp between the bottom surface 42b of any two second placement holes 42 and the bottom surface 114b of the second support layer 114 is no more than 30 nm. That is, the second placement hole 42 produced according to some embodiments of the present disclosure may have uniform size and depth, thereby improving the yield of the semiconductor device.

Refer to FIG. 10. Afterward, a plurality of capacitor structures 410 are formed. These capacitor structures 410 include storage capacitors 410S corresponding to the first placement holes 41 and dummy capacitors 410D corresponding to the second placement holes 42. Therefore, the storage capacitor 410S is in the array region A1, and the dummy capacitor 410D is at the edge of the array region A1. The storage capacitor 410S has a depth d1 and the dummy capacitor 410D has a depth d2. The storage capacitor 410S and the dummy capacitor 410D may have critical dimensions C1 and C2 respectively. Each of the storage capacitor 410S and the dummy capacitor 410D includes a lower electrode 412, a dielectric layer 414, and an upper electrode 416. The lower electrode 412 has, for example, a U-shaped cross section and is in contact with the barrier structure 106. The lower electrode 412 includes, for example, titanium, titanium nitride, tantalum, tantalum nitride, tungsten nitride, or combinations thereof. The lower electrode 412 may include the same material as the first barrier layer 1061, such as titanium nitride. The dielectric layer 414 between the lower electrode 412 and the upper electrode 416 includes a dielectric material with a high dielectric constant (e.g., greater than or equal to 3.9). The upper electrode 416 includes a conductive material with excellent conductivity, such as silicon germanium, high concentration boron doped silicon germanium and other silicon-containing conductive materials, or a combination thereof. After the capacitor structure 410 is formed, other known processes may be performed, such as forming interconnect structures of the peripheral area A2, to complete other components required for the semiconductor device.

In summary, according to the manufacturing method of a semiconductor device proposed in some embodiments of the present disclosure, the placement hole of the capacitor structure (such as a dummy capacitor) at the edge of the array region may have the same or similar size at the top surface of the dielectric material stack, and have consistent or similar depths in the dielectric material stack. As a result, these dummy capacitors also have the same or similar critical size and the same or similar depth. Furthermore, according to the manufacturing method of the present disclosure, the size of the corresponding holes (such as the second hole 1262) of the patterned sacrificial target layer may be adjusted, thereby controlling the opening and depth of the placement hole of the dummy capacitor, so that the placement hole has a predetermined opening size and a predetermined depth in the dielectric material stack, and may be well supported. The smaller the hole of the dummy capacitor's placement hole, the shallower the depth of the subsequently formed placement hole. According to the present disclosure, the depth of the placement hole of the dummy capacitor is smaller than the depth of the placement hole of the storage capacitor. The bottom of the placement hole of the dummy capacitor may stop below and be close to the middle support layer (such as the second support layer 114), so that the placement hole is restricted and sufficiently supported by the top support layer and the middle support layer, and is less likely to collapse, bending or oblique in the dielectric material stack. Therefore, the present disclosure avoids the problem that the placement hole of the dummy capacitor is distorted by stress and causes improper contact with the adjacent placement hole (such as the placement hole of the storage capacitor), thereby avoiding short circuits with subsequently formed capacitor structures (such as storage capacitors).

The invention is suitable for manufacturing miniaturized semiconductor devices to increase the total number of dies on the wafer. Therefore, the present invention reduces the production cost and energy consumption of manufacturing a single IC, and reduces the production energy consumption of subsequent packaging, thereby reducing carbon emissions in the production process of semiconductor devices. In addition, since the yield of the semiconductor device of the present invention is improved, the present invention provides a green semiconductor technology.

What is claimed is:

1. A method of manufacturing a semiconductor device, comprising:
forming a dielectric material stack over a substrate with an array region and a periphery region;
forming a plurality of placement holes of capacitor structures in the dielectric material stack; and
forming the capacitor structures in the placement holes, wherein the capacitor structures comprise:
a plurality of storage capacitors in the array region, wherein each of the storage capacitors has a first critical dimension at a top surface of the dielectric material stack; and
a plurality of dummy capacitors surrounding the storage capacitors, wherein each of the dummy capacitors has a second critical dimension at the top surface of the dielectric material stack, wherein the second critical dimension is smaller than the first critical dimension and larger than one-third of the first critical dimension.

2. The method of manufacturing a semiconductor device as claimed in claim 1, further comprising:
forming a patterned sacrificial layer comprising a plurality of through holes over the dielectric material stack;
forming a plurality of fillers in the through holes, wherein a material of the fillers is different from a material of the patterned sacrificial layer;
forming a patterned mask layer on the patterned sacrificial layer and the fillers, wherein the patterned mask layer exposes the patterned sacrificial layer and the fillers in the array region, and the patterned mask layer covers the patterned sacrificial layer and the fillers in the periphery region;
removing the fillers exposed by the patterned mask layer; and
etching the dielectric material stack after removing the fillers exposed by the patterned mask layer to transfer a combined pattern of the patterned mask layer and the patterned sacrificial layer into the dielectric material stack, and forming the placement holes of the capacitor structures corresponding to the through holes in the dielectric material stack.

3. The method of manufacturing a semiconductor device as claimed in claim 2, further comprising:
forming a sacrificial target layer between the patterned sacrificial layer and the dielectric material stack; and
using the patterned mask layer and the patterned sacrificial layer as a mask to etch the sacrificial target layer, thereby forming a patterned sacrificial target layer, wherein the patterned sacrificial target layer comprises an array pattern and a periphery pattern, and the array pattern and the periphery pattern respectively correspond to the array region and the periphery region, and wherein a combined pattern of the patterned mask layer and the patterned sacrificial layer corresponds to the array pattern and the periphery pattern.

4. The method of manufacturing a semiconductor device as claimed in claim 2, wherein a top surfaces of the fillers are coplanar with a top surface of the patterned sacrificial layer.

5. The method of manufacturing a semiconductor device as claimed in claim 3, further comprising:
forming a polysilicon layer over the dielectric material stack;
forming an oxide layer between the polysilicon layer and the sacrificial target layer; and
forming a nitride layer on the sacrificial target layer, wherein the nitride layer and the sacrificial target layer comprise different materials,
wherein the through holes expose a top surface of the nitride layer,
wherein the nitride layer, the sacrificial target layer, the oxide layer, the polysilicon layer, and the dielectric material stack are sequentially etched according to the mask.

6. The method of manufacturing a semiconductor device as claimed in claim 5, wherein the material of the fillers are different from a material of the nitride layer and the sacrificial target layer.

7. The method of manufacturing a semiconductor device as claimed in claim 6, wherein the fillers comprise an oxide, and the patterned sacrificial layer comprises a polycrystalline silicon.

8. The method of manufacturing a semiconductor device as claimed in claim 2, wherein an opening edge of the patterned mask layer is adjacent to an edge of the array region.

9. The method of manufacturing a semiconductor device as claimed in claim 3, wherein the array pattern of the patterned sacrificial target layer comprises:
a plurality of first holes corresponding to a positions of storage capacitors of the capacitor structures subsequently formed in the dielectric material stack; and
a plurality of second holes corresponding to a positions of the dummy capacitors of the capacitor structures subsequently formed in the dielectric material stack, wherein the second holes are adjacent to the periphery pattern of the patterned sacrificial target layer, and each of the second holes is smaller than each of the first holes.

10. The method of manufacturing a semiconductor device as claimed in claim 1, wherein the placement holes of the capacitor structures comprise:
a plurality of first placement holes in the array region, wherein the storage capacitors of the capacitor structures are disposed in the first placement holes; and
a plurality of second placement holes surrounding the first placement holes, wherein the dummy capacitors of the capacitor structures are disposed in the second placement holes, and each of the second placement holes is smaller than each of the first placement holes,
wherein each of the second placement holes has a critical dimension, a difference between a maximum value and a minimum value of critical dimensions among the second placement holes is less than one-tenth of an average value of the critical dimensions among the second placement holes.

11. The method of manufacturing a semiconductor device as claimed in claim 1, wherein the placement holes of the capacitor structures comprise:
a plurality of first placement holes in the array region, wherein the storage capacitors of the capacitor structures are disposed in the first placement holes; and
a plurality of second placement holes surrounding the first placement holes, wherein the dummy capacitors of the capacitor structures are disposed in the second placement holes, and each of the second placement holes is smaller than each of the first placement holes, wherein
the dielectric material stack comprises a first support layer, a second support layer and a third support layer, wherein the second support layer is between the first support layer and the third support layer,
each of the second placement holes passes through the third support layer and the second support layer, and extends beyond a bottom surface of the second support layer, without making contact with the first support layer, and
each of the first placement holes passes through the third support layer, the second support layer, and the first support layer, making contact with a contact plug below the dielectric material stack.

12. The method of manufacturing a semiconductor device as claimed in claim 11, wherein a ratio of a vertical distance from the bottom surface of each of the second placement holes to the bottom surface of the second support layer and a distance from the first support layer to the second support layer is ranged from 0.01 to 0.2.

13. A semiconductor device, comprising:
a substrate with an array region and a periphery region;
a dielectric material stack over the substrate; and
a plurality of capacitor structures in the dielectric material stack, wherein the capacitor structures comprise:
a plurality of storage capacitors in the array region, wherein each of the storage capacitors has a first critical dimension at a top surface of the dielectric material stack; and
a plurality of dummy capacitors surrounding the storage capacitors, wherein each of the dummy capacitors has a second critical dimension at the top surface of the dielectric material stack, and wherein second critical dimensions of the dummy capacitors are smaller than the first critical dimension and are larger than one-third of the first critical dimension.

14. The semiconductor device as claimed in claim 13, wherein a difference between a maximum value and a minimum value of a second critical dimensions among the dummy capacitors is less than one-tenth of an average value of the second critical dimensions.

15. The semiconductor device as claimed in claim 13, wherein the storage capacitors have a first depth in the dielectric material stack, the dummy capacitors have a second depth in the dielectric material stack, and the second depth is less than the first depth.

16. The semiconductor device as claimed in claim 13, wherein the dielectric material stack comprises a first support layer, a second support layer and a third support layer, wherein the second support layer is between the first support layer and the third support layer, each of the dummy capacitors passes through the third support layer and the second support layer, and extends beyond a bottom surface of the second support layer without making contact with the first support layer, each of the storage capacitors passes through the third support layer, the second support layer and the first support layer, and contacts a contact plug below the dielectric material stack.

17. The semiconductor device as claimed in claim 16, wherein a distance between the bottom surface of each of the dummy capacitors and the bottom surface of the second support layer is less than a distance between the bottom surface of each of the dummy capacitors and a top surface of the first support layer.

18. The semiconductor device as claimed in claim 16, wherein a ratio of a vertical distance from the bottom surface of each of the dummy capacitors to the bottom surface of the second support layer and a distance from the first support layer to the second support layer is ranged from 0.01 to 0.2.

19. The semiconductor device as claimed in claim 16, wherein a difference between vertical distances from bottom surfaces of any two of the dummy capacitors to a bottom surface of the second support layer is less than 30 nm.
